(19) United States
(12) Patent Application Publication
(10) Pub. No.: US 2025/0383392 A1
(43) Pub. Date: Dec. 18, 2025

(54) TIME-DEPENDENT DIELECTRIC BREAKDOWN (TDDB) TEST UNIT CIRCUIT, MEASUREMENT CIRCUIT, AND METHOD THEREOF

(71) Applicant: TAIWAN SEMICONDUCTOR MANUFACTURING COMPANY, LTD., Hsinchu (TW)

(72) Inventors: Kuo-Yu CHOU, Hsinchu (TW); Chi-Hung LO, Hsinchu (TW)

(21) Appl. No.: 18/897,751

(22) Filed: Sep. 26, 2024

Related U.S. Application Data
(60) Provisional application No. 63/658,978, filed on Jun. 12, 2024.

(51) Int. Cl. G01R 31/14; G01R 31/18

(52) U.S. Cl. CPC G01R 31/14; G01R 31/18

(57) ABSTRACT

A measurement circuit is provided. The measurement circuit includes an array including a plurality of test unit circuits arranged in rows and columns, a plurality of first test lines, a plurality of address lines and a control circuit connected to the plurality of address lines. Each test unit circuit includes a device under test, a resistor coupled in series with the device under test between an input terminal and an intermediate node, a first switch coupled between the intermediate node and a node of a reference voltage, and a second switch coupled between the intermediate node and an output terminal. Each first test line is connected to the first switches of the test unit circuits in a corresponding column of the array. Each address line is connected to the second switches of the test unit circuits in a corresponding row of the array.

### CROSS-REFERENCE TO RELATED APPLICATIONS

This application claims the benefit of U.S. Provisional Application No. 63/658,978, filed Jun. 12, 2024, the entirety of which is incorporated by reference herein.

### BACKGROUND

In some reliability qualifications for semiconductor devices, a time-dependent dielectric breakdown (TDDB) test is performed to electrically measure and evaluate breakdown voltage in a dielectric layer, and to measure and evaluate the time required for breakdown.

With integration of semiconductor devices and decreased thickness of dielectric layers (such as gate dielectric layers), time required for TDDB testing increases. Furthermore, the TDDB test is performed on each device on the semiconductor substrate. As a result, the time required increases.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a circuit diagram of a measurement circuit for performing a TDDB test, in accordance with some embodiments of the disclosure.

FIG. 2 is a circuit diagram of a test unit circuit in the measurement circuit of FIG. 1, in accordance with some embodiments of the disclosure.

FIG. 3A and FIG. 3B are respectively a waveform diagram and a table of signals in the test unit circuit of FIG. 2, in accordance with some embodiments of the disclosure.

FIG. 4 is a flow chart of a measurement method for performing a TDDB test in an array formed by the test unit circuits of FIG. 2, in accordance with some embodiments of the disclosure.

FIG. 5 is a time chart that illustrates timings of global stress operations and read operations of the measurement method of FIG. 4, in accordance with some embodiments of the disclosure.

FIG. 6 includes schematic views of an array of test unit circuits at various stages in an operating process of the measurement method of FIG. 4, in accordance with some embodiments of the disclosure.

FIG. 7 is a graph showing a relationship between the stress voltage and the stress time in multiple global stress operations, in accordance with some embodiments of the disclosure.

FIGS. 8A through 8D are circuit diagrams of various test unit circuits, in accordance with some embodiments of the disclosure.

FIGS. 9A through 9E are circuit diagrams of various test unit circuits, in accordance with some embodiments of the disclosure.

FIG. 10 is a circuit diagram of a test unit circuit, in accordance with some embodiments of the disclosure.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Various semiconductor wafer circuits are provided in accordance with various exemplary embodiments. Some variations of some embodiments are discussed. Throughout the various views and illustrative embodiments, like reference numbers are used to designate like elements.

Time-dependent dielectric breakdown (TDDB) is a potential issue related to aging of semiconductor devices or transistors in integrated circuits (ICs). As transistors age, there is a likelihood that a dielectric material of the transistors, e.g., a gate dielectric layer, break down due to the prolonged operational periods, causing an undesirable leakage current through the gate dielectric layer. A TDDB test is performed, in some embodiments, several times, for evaluation of IC reliability.

According to some embodiments of the present disclosure, a high level stress voltage is applied to multiple test unit circuits of an array for a TDDB test during each global stress operation, thereby decreasing test time. After one or more global stress operations, a low level stress voltage is applied to the test unit circuits and the rows of the array are read respectively, so as to measure the leakage current of the test unit circuits in the same row to identify and flag any leaky test unit circuit in the corresponding row. In each test unit circuit, a device under test is connected with a resistor in series, and the resistor has a higher resistance than an equivalent resistance of the device under test, thereby protecting the device under test from high stress voltage in one or more embodiments. The subsequent global stress operations are performed on the array, bypassing read operations of the flagged leaky test unit circuits, thereby improving the accuracy for measuring TDDB in one or more embodiments.

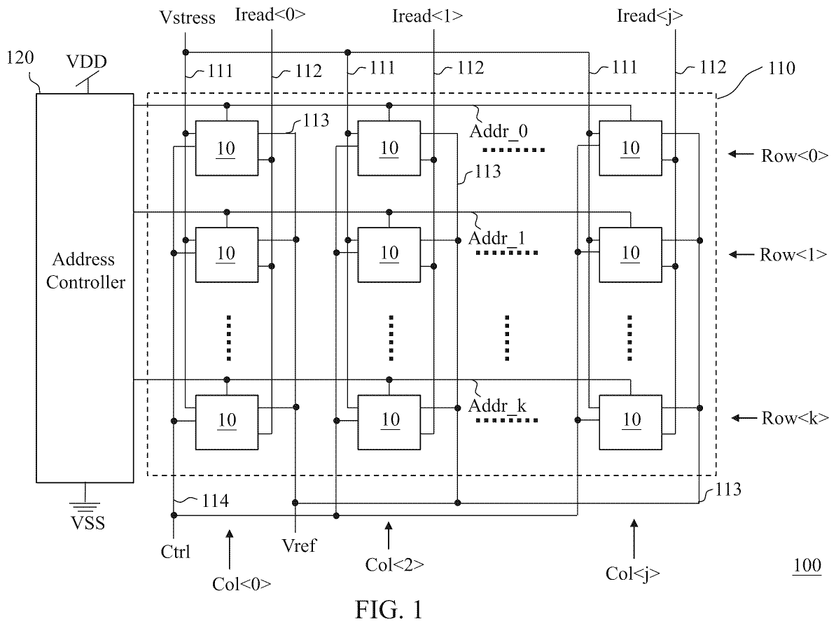

FIG. 1 is a measurement circuit 100 for performing a TDDB test, in accordance with some embodiments of the disclosure. The measurement circuit 100 is implemented in a wafer or substrate, e.g., a semiconductor wafer, containing circuitry. The measurement circuit 100 includes an array 110 and an address controller 120. The array 110 includes multiple test unit circuits 10 arranged in the rows Row<0> through Row<k> and the columns Col<0> through Col<j>. In some embodiments, the test unit circuits 10 are arranged at various regions of the circuitry on the wafer for testing or evaluating reliability of the circuits in those regions. The address controller 120 is operated in a power domain provided by a high power supply voltage VDD and a low power supply voltage VSS. In some embodiments, the low power supply voltage VSS is a grounding voltage. The address controller 120 is configured to provide the address signals Addr_0 through Addr_k to the rows Row<0> through Row<k> of the array 110, respectively. The address controller 120 is sometimes referred to as a control circuit and/or is configured to, in one or more embodiments, to perform one or more operations other than providing address signals. For example, in at least one embodiment, one or more operations described herein as being performed by a test machine is/are performed by the control circuit or address controller 120.

The test unit circuits 10 arranged in the same row are addressed by the same address signal Addr on a corresponding conductive address line from the address controller 120. For example, the test unit circuits 10 arranged in the row Row<0> can be selected (or addressed) by the address signal Addr_0, and the test unit circuits 10 arranged in the row Row<k> can be selected (or addressed) by the address signal Addr_k. For simplicity, an address line and a corresponding address signal thereon are designated by the same reference numeral. For example, Addr_0 designates both the address line coupling the address controller 120 to the test unit circuits 10 arranged in the row Row<0>, and the address signal supplied from the address controller 120 to the test unit circuits 10 arranged in the row Row<0>. In some embodiments, the address controller 120 includes a shift register. In response to a clock signal and a reset signal (not shown) from the test machine, the shift register is configured to sequentially assign or enable the address signals Addr_0 through Addr_k.

The test unit circuits 10 arranged in the same column are coupled to the same set of test lines 111 through 114. Each test line 111 is configured to receive a stress voltage Vstress provided by a test machine through the same input/output (I/O) pad of the semiconductor wafer. The test machine is configured to provide the stress voltage Vstress with a voltage level VL1 during a global stress operation and a voltage level VL2 during a read operation, and the voltage level VL1 exceeds the voltage level VL2. In some embodiments, the voltage level VL1 exceeds 10V. Furthermore, the test lines 111 of the columns Col<0> through Col<j> are connected together. Each test line 112 is configured to provide a measurement current (or a measurement voltage) Iread to the test machine through an I/O pad of the semiconductor wafer. The test lines 112 of the columns Col<0> through Col<j> are separated from each other, and the measurement currents Iread<0> through Iread<j> are provided to the test machine through the individual I/O pads of the semiconductor wafer. Each test line 113 is configured to receive a reference voltage Vref provided by the test machine through the same I/O pad of the semiconductor wafer, i.e., the test lines 113 of the columns Col<0> through Col<j> are connected together. In some embodiments, the reference voltage Vref has difference voltage levels during the global stress operation and the read operation. In some embodiments, the reference voltage Vref has the same voltage level during the global stress operation and the read operation. In some embodiments, the reference voltage Vref is the low power supply voltage VSS. Each test line 114 is configured to receive a control signal Ctrl provided by the test machine through the same I/O pad of the semiconductor wafer, i.e., the test lines 114 of the columns Col<0> through Col<j> are connected together.

In the array 110, each test unit circuit 10 includes a device under test (DUT). Each test unit circuit 10 is controlled by the control signal Ctrl and the corresponding address signal Addr to connect the device under test to a stress path during the global stress operation or a read path during the read operation, and the stress path is independent of the read path. During the global stress operation, the stress voltage Vstress with the voltage level VL1 is applied to the test unit circuits 10 through the test lines 111, and the DUT of each test unit circuit 10 is connected to the stress path in response to the control signal Ctrl. Furthermore, during the read operation, the stress voltage with the voltage level VL2 is applied to the test unit circuits 10 through the test lines 111, and the currents Iread<0> through Iread<j> of the test unit circuits 10 selected by the address signal Addr are measured through the test lines 112, so as to determine whether the DUT of the test unit circuit has a large leakage current, i.e., a leakage current equal to or greater than a predetermined current level. When determining that the DUT of the test unit circuit has a large leakage current (i.e., the test unit circuit is a leaky test unit circuit), the test machine is configured to flag the leaky test unit circuit as damaged and record the address (e.g., by the row of the corresponding address signal Addr and the column of the corresponding measurement current Iread) of the leaky test unit circuit in the array 110, i.e., a dielectric material of the DUT has broken down.

Using the measurement circuit 100, stress, such as, constant stress, is applied to the DUT of each test unit circuit 10 of the array 110. In some embodiments, the constant stress is applied in the form of constant voltage stress (CVS) or constant current stress. In some embodiments, the stress voltage (often lower than a breakdown voltage of an oxide, a dielectric material, or a gate dielectric for a transistor) is applied to a gate of the transistor, and then a leakage current thereof is being monitored. Furthermore, the time it will take for the oxide, dielectric material, or gate dielectric to break under the constant stress voltage applied is referred to as time-to-failure. The TDDB test is repeated several times to obtain a distribution of time-to-failure. These distributions are used to create reliability plots and predict the TDDB behavior of oxide, dielectric material, or gate dielectric at other voltages.

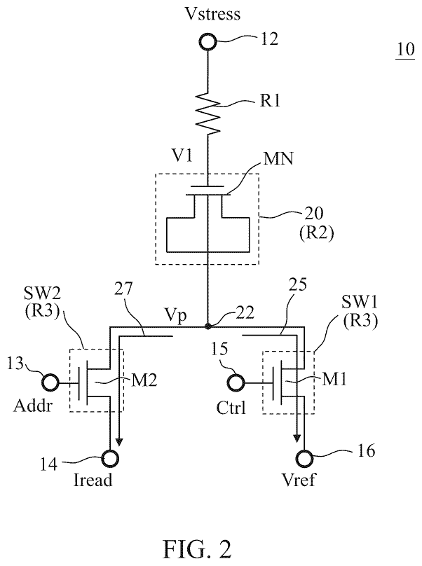

FIG. 2 is a circuit diagram of a test unit circuit 10 in the measurement circuit 100 of FIG. 1, in accordance with some embodiments of the disclosure. The test unit circuit 10 has an input terminal 12, control terminals 13 and 15, an output terminal 14, and a reference terminal 16. The input terminal 12 is connected to the corresponding test line 111 of FIG. 1 to receive the stress voltage Vstress from the test machine. The control terminal 13 is connected to the corresponding address line of FIG. 1 to receive the address signal Addr from the address controller 120. The control terminal 15 is connected to the test line 114 of FIG. 1 to receive the control signal Ctrl from the test machine. The output terminal 14 is connected to the corresponding test line 112 of FIG. 1 to provide the current Iread (e.g., the leakage current of the DUT 20) to the test machine. The reference terminal 16 is connected to the corresponding test line 113 of FIG. 1 to receive the reference voltage Vref provided by the test machine, i.e., the reference terminal 16 corresponds to a node of the reference voltage Vref.

The test unit circuit 10 includes a resistor R1, a DUT 20 and switches SW1 and SW2. Resistor R1 is connected between the input terminal 12 and the DUT 20, and the DUT 20 is connected between the resistor R1 and an intermediate node 22. In other words, the resistor R1 and the DUT 20 are coupled in series between the input terminal 12 and the intermediate node 22. The DUT 20 has an equivalent resistance R2 lower than resistor R1, i.e., R1>R2. In the example embodiment of FIG. 2, the DUT 20 is an N-type transistor MN. The gate of the N-type transistor MN is connected to the resistor R1, and the bulk of the N-type transistor MN is connected to the intermediate node 22. Furthermore, the source and drain of the N-type transistor MN are connected to each other. A voltage V1 is a voltage of a node between the resistor R1 and the N-type transistor MN. In the example embodiment in FIG. 2, the voltage V1 represents a gate voltage of the N-type transistor MN. A voltage Vp represents the voltage at the intermediate node 22 (i.e., a bulk voltage of the N-type transistor MN in the example embodiment in FIG. 2). The resistor R1 is configured as a current limiting resistor for limiting the leakage current of the DUT 20 when the DUT 20 is broken down. In some embodiments, the resistor R1 has a high resistance (e.g., 1 KΩ to 10 MΩ). In some embodiments, the resistor R1 is a poly resistor and/or a metal resistor. An example poly resistor is a resistor formed by polysilicon (poly) gate sections of transistors in the circuitry on the wafer. An example metal resistor is a resistor formed by metal patterns in one or more metal layers over the transistors in the circuitry and/or other metal features constituting the circuitry. In some embodiments, the resistor R1 includes a combination of one or more poly resistors and one or more metal resistors.

The switch SW1 is connected between the intermediate node 22 and the reference terminal 16, and controlled by the control signal Ctrl. When the switch SW1 is turned on by the control signal Ctrl, the turned-on switch SW1 is configured to provide the stress path 25 for the DUT 20. The switch SW2 is connected between the intermediate node 22 and the output terminal 14, and is controlled by the address signal Addr. When the switch SW2 is turned on by the address signal Addr, the turned-on switch SW2 is configured to provide the read path 27 for the DUT 20. The switches SW1 and SW2 are switching devices with an equivalent resistance R3 (when the switches are turned ON) lower than the equivalent resistance R2, i.e., R2>R3. Furthermore, resistance of resistor R1 is significantly higher than the equivalent resistance R3, i.e., R1>>R3. In the example embodiment of FIG. 2, the switches SW1 and SW2 are formed by N-type transistors M1 and M2. In some embodiments, the switches SW1 and SW2 are formed by the P-type transistors or other type of switching devices, or one of the switches is an N-type transistor and the other of the switches is a P-type transistor. Furthermore, the stress path 25 is independent of the read path 27.

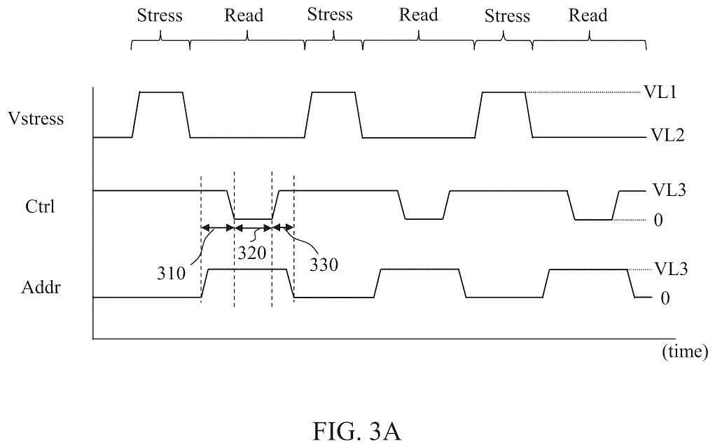

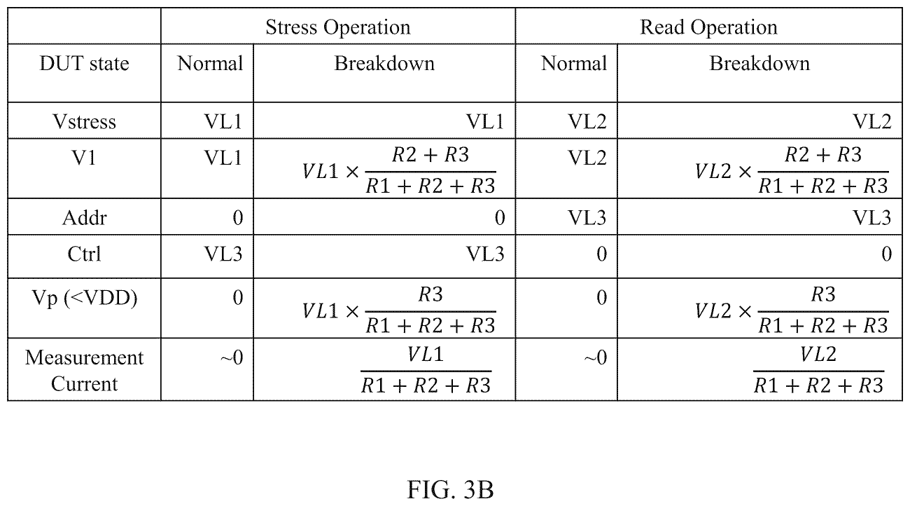

FIG. 3A and FIG. 3B are respectively a waveform diagram and a table of signals in the test unit circuit 10 of FIG. 2, in accordance with some embodiments of the disclosure. In some embodiments, the test machine (or a processor or a control circuit thereof) is configured to alternately perform a stress operation and a read operation on the test unit circuit 10 and, if a test result shows that the test unit circuit 10 is damaged, flag the test unit circuit 10 as damaged. In some embodiments, the stress operation described with respect to FIGS. 3A-3B is a global stress operation performed simultaneously for more than one, or all, test unit circuits 10 in an array. In the example in FIG. 3A, several test cycles, each including one stress operation and one read operation, are performed.

During the stress operation (shown as “Stress” in FIG. 3A), the stress voltage Vstress with the voltage level VL1 (e.g., 2V) is applied to the test unit circuit 10. The switch SW1 is turned on by the control signal Ctrl with a voltage level VL3. Moreover, the switch SW2 is turned off by the address signal Addr, and the voltage level of the address signal Addr is 0. Therefore, the DUT 20 is connected to a stress path formed by the switch SW1. In some embodiments, the voltage levels VL2 and VL3 equals a power supply voltage VDD, e.g., 0.75V. When the DUT 20 is normal, no leakage current flows through the DUT 20 to the stress path. Thus, the voltage V1 substantially equals the stress voltage Vstress, the voltage Vp substantially equals 0, and the current on the stress path (e.g., through the reference terminal 16) substantially equals 0. When the DUT 20 is broken down, a leakage current flows through the DUT 20 to the stress path. Thus, the voltage V1 substantially equals 1×R2+R3/R1+R2+R3, the voltage Vp substantially equals VL1×R3/R1+R2+R3, and the current on the stress path (e.g., through the reference terminal 16) substantially equals

$$\frac{V L 1}{R 1 + R 2 + R 3} .$$

As described, the resistor R1 has a high resistance, which can provide a large voltage drop when the leakage current is present, thereby protecting the DUT 20 from high stress voltage. Furthermore, in one or more embodiments, the resistance of the resistor R1 and/or the voltage level VL1 is/are chosen/configured appropriately so that voltage Vp is lower than the high power supply voltage VDD when the DUT 20 is broken down. For the test machine, the maximum stress current equals

$$\frac{V L 1}{R 1 + R 2 + R 3}$$

multiplied by the number (e.g., N) of all test unit circuits 10 in the array 110 when all test unit circuits 10 are broken down. In some embodiments, one or more of VL1, R1 and N are chosen/configured appropriately so that the maximum stress current is at or below an acceptable predetermined current level.

During the read operation (shown as “Read” in FIG. 3A), the stress voltage Vstress with the voltage level VL2 (e.g., 0.75V or the high power supply voltage VDD) is applied to the test unit circuit 10, thereby avoiding the high stress voltage from stressing the DUT 20. In the example embodiment of FIG. 3A, the read operation includes three time periods 310, 320, and 330 to prevent both switches SW1 and SW2 from being both turned off during the transition of the control signal Ctrl and the address signal Addr, thereby ensuring that at least one of the read path and the stress path exists. In the time periods 310 and 330, the switches SW1 and SW2 are turned on, and the stress path and the read path are both present. In the time period 320, the switch SW1 is turned off by the control signal Ctrl (e.g., 0V), and the switch SW2 is turned on by the address signal Addr (e.g., VL3). A leakage current of the DUT 20 is measured in the time period 320 when only the read path is present. When the DUT 20 is normal, no leakage current flows through the DUT 20 to the read path. Thus, the voltage V1 substantially equals the stress voltage Vstress, the voltage Vp substantially equals 0, and the current Iread measured from the read path (e.g., through the output terminal 14) substantially equals 0. When the DUT 20 is broken down, a leakage current flows through the DUT 20 to the read path. Thus, the voltage V1 substantially equals

$$2 \times \frac{R 2 + R 3}{R 1 + R 2 + R 3} ,$$

the voltage Vp substantially equals and

$$V L 2 \times \frac{R 3}{R 1 + R 2 + R 3} ,$$

the current Iread measured from the read path (e.g., through the output terminal 14) substantially equals

$$\frac{V L 2}{R 1 + R 2 + R 3} .$$

The voltage level VL2 is lower than the voltage level VL1, thereby protecting the DUT 20 from continuing to be subjected to the high stress voltage (e.g., with the voltage level VL1) during the read operation. In other words, the DUT 20, if already damaged, will not be further damaged during the read operation.

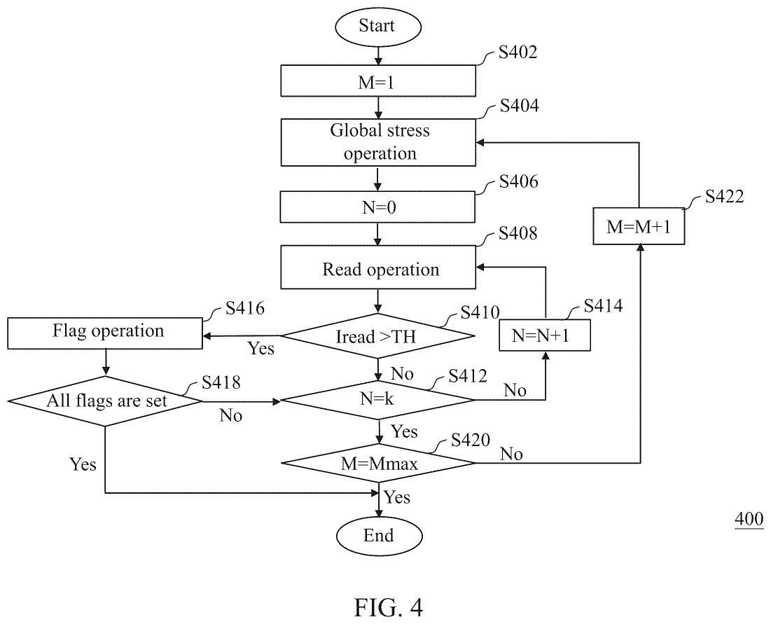

FIG. 4 is a flow chart of a measurement method 400 for performing a TDDB test in the array 110 formed by the test unit circuits 10 of FIG. 2, in accordance with some embodiments of the disclosure. The measurement method 400 is performed by a test machine (not shown). In some embodiments, the test machine includes a processor (or a controller or a control circuit) and a memory.

Referring to FIG. 2 and FIG. 4, in operation S402, a parameter M is set to 1 by the processor. In some embodiments, the parameter M represents the number of global stress operations (or test cycles) executed at present.

In operation S404, a global stress operation is performed on the array 110. In at least one embodiment, the global stress operation at each test unit circuit 10 of the array 110 is performed as described with respect to FIGS. 3A-3B. During the global stress operation, the switch SW1 is turned on and the switch SW2 is turned off in each test unit circuit 10 of the array 110. The stress voltage Vstress with the voltage level VL1 (e.g., 2V) is applied to all test unit circuits 10 in the array 110. The stress voltage Vstress is applied to the DUT 20 through the resistor R1 in each test unit circuit 10. As described in FIG. 3B, when the DUT 20 is normal, no leakage current is present, and the voltage V1 applied to the DUT 20 substantially equals the stress voltage Vstress. Furthermore, when the DUT 20 is damaged, the voltage V1 applied to the DUT 20 is reduced by the resistor R1, thereby reducing the stress on the DUT 20.

In operation S406, a parameter N is set to 0 by the processor after the global stress operation is completed. In some embodiments, the parameter N represents the row Row<N> of the array 110 on which a read operation is to be performed.

In operation S408, a read operation is performed on the row Row<N>, e.g., a read operation is performed on the row Row<0>. In at least one embodiment, the read operation at each test unit circuit 10 of the row Row<N> is performed as described with respect to FIGS. 3A-3B. During the read operation, the stress voltage Vstress with the voltage level VL2 (e.g., 0.75V or the high power supply voltage VDD) is applied to all test unit circuits 10 in the array 110. Furthermore, the address controller 120 supplies an address signal Addr to the address line coupled to test unit circuits 10 in the row Row<N> to select the row Row<N>. Thus, each test unit circuit 10 in the row Row<N> is selected by the address controller 120. The other rows and the test unit circuits 10 thereof are not selected by the address controller 120 in the read operation of the row Row<N>.

In response to the address signal Addr having a high voltage level (e.g., the power supply voltage VDD) and the control signal Ctrl having a low voltage level (e.g., the low power supply voltage VSS), the switch SW2 is turned on in each test unit circuit 10 in the selected row Row<N>, and the current Iread from the output terminal 14 is measured by the test machine through the corresponding test line 112 in each of the columns Col<0> through Col<j>. For example, the current Iread<0> represents the measurement current of the DUT 20 in the test unit circuit 10 arranged in the selected row Row<N> and the column Col<0>, the current Iread<1> represents the measurement current of the DUT 20 in the test unit circuit 10 arranged in the selected row Row<N> and the column Col<1>, and so on.

In operation S410, it is determined whether the current Iread exceeds a threshold value TH. In some embodiments, the threshold value TH is predetermined according to a specification of the DUT 20. If the current Iread does not exceed the threshold value TH, the measurement method 400 enters operation S412.

In operation S412, it is determined whether the parameter N equals k, i.e., it is determined whether the last row Row<k> has completed the read operation. If the parameter N is not equal to k, the measurement method 400 enters the operation S414, and the parameter N is updated or set to the current value plus 1, i.e., N=N+1.

After updating the parameter N, for example, updating to N=1, the measurement method 400 returns to operation S408, and a read operation is performed on the row corresponding to the update parameter N, e.g., the row Row<1>. For example, during the read operation, for each test unit circuit 10 in the selected row Row<1>, the stress voltage Vstress with the voltage level VL2 from the test machine is applied to the input terminal 12 and a current Iread from the output terminal 14 measured by the test machine.

In operation S410, after measuring the current Iread, it is determined whether the current Iread exceeds the threshold value TH. If so, the measurement method 400 enters operation S416. During the read operation, the test unit circuit 10 having the current Iread exceeding the threshold value TH is considered a leaky test unit circuit.

In operation S416, the test machine is configured to perform a flag operation for the leaky test unit circuit 10 of the current row. In some embodiments, the leaky test unit circuit 10 is flagged as damaged in the memory of the test machine. In at least one embodiment, the location of the leaky test unit circuit 10 is stored in the memory of the test machine as a flag map. Once the test unit circuit 10 is flagged, the test machine may omit measuring, or may ignore, the current Iread of the flagged test unit circuit in subsequent reading operations, thereby decreasing the measurement time for TDDB test.

In operation S418, after completing the flag operation, it is determined whether all flags of the test unit circuits 10 in the array 110 are set in the flag map of the test machine. If all flags of the test unit circuits 10 in the array 110 are set, i.e., all test unit circuits 10 in the array 110 are leaky, the measurement method 400 is completed. Conversely, if there is/are still one or more unflagged test unit circuits 10 in the array 110, the measurement method 400 enters the operation S412.

In the operation S412, if the parameter N is not equal to k, the measurement method 400 enters the operation S414 and then returns to operations S408, so as to perform the read operation of the next row until the parameter N equals k (operation S412) or all test unit circuits 10 in the array 110 are flagged as leaky (Yes from operation S418). If the parameter N equals k, the measurement method 400 enters the operation S420.

In operation S420, it is determined whether the parameter M equals a maximum value Mmax, and the value Mmax represents the maximum number of the global stress operations (or test cycles) to be performed for TDDB test. If the parameter M equals the maximum value Mmax, the measurement method 400 is completed. Conversely, if the parameter M is not equal to the maximum value Mmax, the measurement method 400 enters the operation S422, and the parameter M is updated or set to the current value plus 1, i.e., M=M+1.

After updating the parameter M, for example, updating to M=2, the measurement method 400 returns to operation S404, and a global stress operation is performed on the array 110 again, and then the following read operations are performed row by row until all flags are set (Yes from operation S418) or the parameter M equals the value Mmax (Yes from operation S420), and then the measurement method 400 is completed. According to operation time of the measurement method 400 and the flagged test unit circuits in the flag map, the time required for breakdown is evaluated for reliability of the DUT 20.

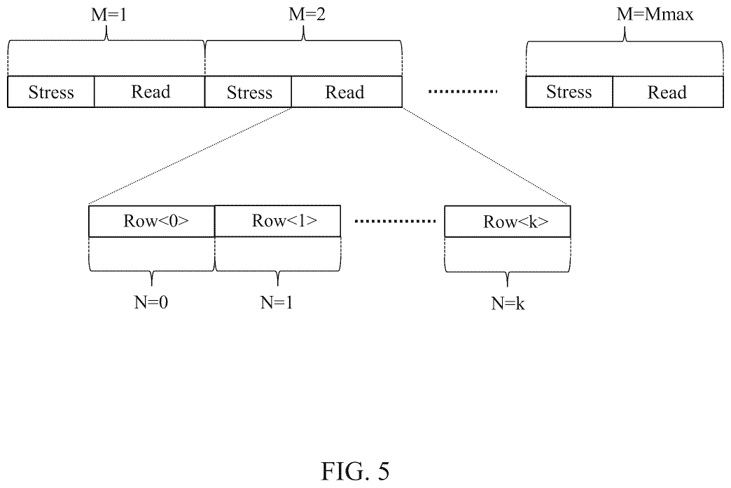

FIG. 5 is a time chart that illustrates timings of the global stress operations and the read operations of the measurement method 400 of FIG. 4, in accordance with some embodiments of the disclosure.

In the example embodiment of FIG. 5, the global stress operation (shown as “Stress”) and the read operation (shown as “Read”) are alternately performed on the test unit circuits 10 of the array 110 according to the measurement method 400 of FIG. 4, i.e., the number of global stress operations performed equals the number of read operations performed. In some embodiments, each read operation is performed after multiple consecutive global stress operations, i.e., the number of global stress operations performed exceeds the number of read operations performed. In some embodiments, the global stress operations have different stress times. For example, the stress time (i.e., the duration of Vstress having the voltage level VL1) is set to 1 second when the parameter M is between 0 and 99, and 5 seconds when the parameter M is between 100 and 199.

In FIG. 5, the parameter M is set to 1 initially (e.g., the operation S402 of FIG. 4), and then gradually increased to the maximum Mmax (e.g., the operation S422 of FIG. 4). During each read operation, the rows Row<0> through Row<k> of the array 110 are read in sequence, and a corresponding flag operation (such as the operation S416 of FIG. 4) is performed for each row.

The stress voltage Vstress having the voltage level VL1 (e.g., 2V) is applied to the test unit circuit 10 during each global stress operation, and the stress voltage Vstress having the voltage level VL2 (e.g., 0.75V) is applied to the test unit circuit 10 during each read operation. In some embodiments, the DUTs 20 of the test unit circuits 10 arranged in the same row or same column have the same size or different sizes.

According to the measurement method 400 and the measurement circuit 100, multiple DUTs 20 of the array 110 are tested simultaneously, i.e., a stress time of the global stress operation is shared with all rows of the array 110. Therefore, compared with other approaches which only measure a single DUT at a time, a global stress operation of the measurement method 400 reduces the measurement time, thereby increasing throughput and pattern density for TDDB test. The pattern density represents the number of DUTs 20 on the wafer. In some embodiments, an improvement of more than 40 times in TDDB pattern density and/or more than 30 times in TDDB throughput is achievable.

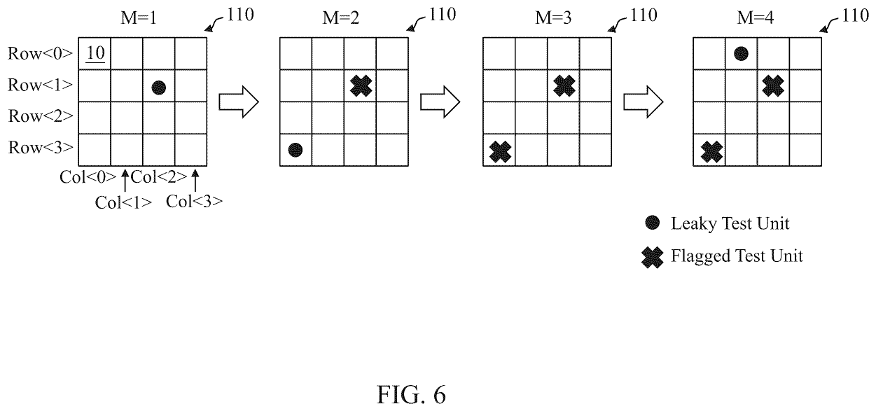

FIG. 6 includes schematic views of an array of test unit circuits at various stages in an operating process of the measurement method 400 of FIG. 4, in accordance with some embodiments of the disclosure. In FIG. 6, the array 110 includes the test unit circuits 10 arranged in the rows Row<0> through Row<3> and the columns Col<0> through Col<3>.

First, the parameter M is set to 1, and a first global stress operation is performed on all test unit circuits 10 in the array 110. During a read operation in the row Row<1>, the test unit circuit 10 in the column Col<2> has the current Iread exceeding the threshold value TH, i.e., the test unit circuit 10 is a leaky test unit circuit. Thus, the test machine is configured to flag the leakage test unit circuit as a first flagged test unit circuit in the flag map, and to omit measuring the current Iread of the first flagged test unit circuit in subsequent reading operations.

Next, the parameter M is set to 2, and a second global stress operation is performed on all test unit circuits 10 of the array 110. During a read operation in the row Row<3>, the test unit circuit 10 in the column Col<0> has the current Iread exceeding the threshold value TH, i.e., the test unit circuit 10 is a leaky test unit circuit. Thus, the test machine is configured to flag the leakage test unit circuit as a second flagged test unit circuit in the flag map, and to omit measuring the current Iread of the second flagged test unit circuit in subsequent reading operations.

Next, the parameter M is set to 3, and a third global stress operation is performed on all test unit circuits 10 of the array 110. During each read operation in the rows, no test unit circuit 10 has current Iread exceeding the threshold value TH, i.e., no leaky test unit circuit is present.

Next, the parameter M is set to 4, and a fourth global stress operation is performed on the test unit circuits 10 of the array 110. During a read operation in the row Row<0>, the test unit circuit 10 in the column Col<I> has current Iread exceeding the threshold value TH, i.e., the test unit circuit 10 is a leaky test unit circuit. Thus, the test machine is configured to flag the leakage test unit circuit as a third flagged test unit circuit in the flag map, and to omit measuring the current Iread of the third flagged test unit circuit in subsequent reading operations.

The measurement method 400 continues to be performed until all test unit circuits 10 are flagged or the number of global stress operations has reached the maximum value Mmax. The defect DUT 20 in the test unit circuit 10 becomes leaky during the global stress operations. With time, more leaky test unit circuits 10 are identified. Using the resistor R1 with high resistance to limit the leakage current in the corresponding leaky test unit circuit, no accumulated large leakage current will induce a large voltage drop for the stress voltage Vstress. Thus, in one or more embodiments, despite one or more leaky test unit circuits, the stress voltage Vstress can be kept substantially constant in a global stress operation to properly stress the other, unflagged test unit circuits.

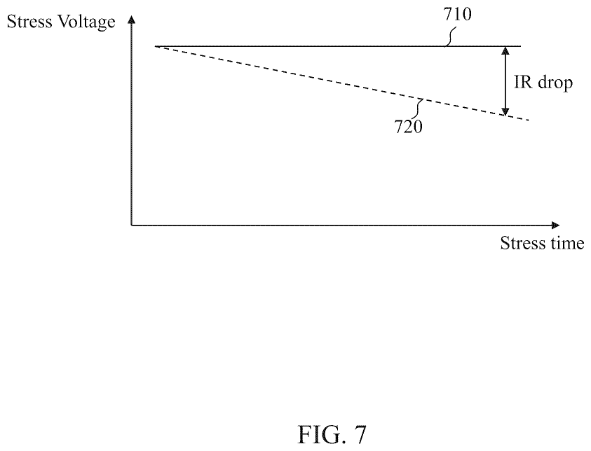

FIG. 7 is a graph showing a relationship between the stress voltage Vstress and the stress time in multiple global stress operations, in accordance with some embodiments of the disclosure. The label 710 represents the stress voltage Vstress applied at the input terminal 12 of the test unit circuit 10 in which the DUT 20 is connected in series with the resistor R1, and the label 720 represents the stress voltage Vstress applied at a DUT 20 with no resistor R1 connected in series, in which case, the leakage current of each leaky test unit circuit is increased with the stress time of the global stress operation. As leakage current increases, the parasitic impedance of the test path from the test machine to the array 110 results in a larger IR drop (voltage drop) for the stress voltage Vstress. Therefore, the stress voltage Vstress applied to the test unit circuit without the resistor R1 is not as expected, resulting in inaccurate test results. In some embodiments, by connecting the resistor R1 in series with each DUT, the described issue with a large IR drop when the resistor R1 is not provided is avoidable or at least mitigatable.

In at least one embodiment, even with the resistor R1 connected in series with each DUT, there is still a potential IR drop of the stress voltage Vstress in a global stress operation, due to a large number of leaky test unit circuits. The maximum IR drop of the stress voltage Vstress equals the maximum stress current (e.g.,

$$\frac{V L 1}{R 1 + R 2 + R 3}$$

multiplied by the number of all (e.g., N) test unit circuits 10) multiplied by the parasitic impedance. In some embodiments, one or more of R1, N and parasitic impedance are selected or configured so that the maximum IR drop is at or below a predetermined, acceptable value.

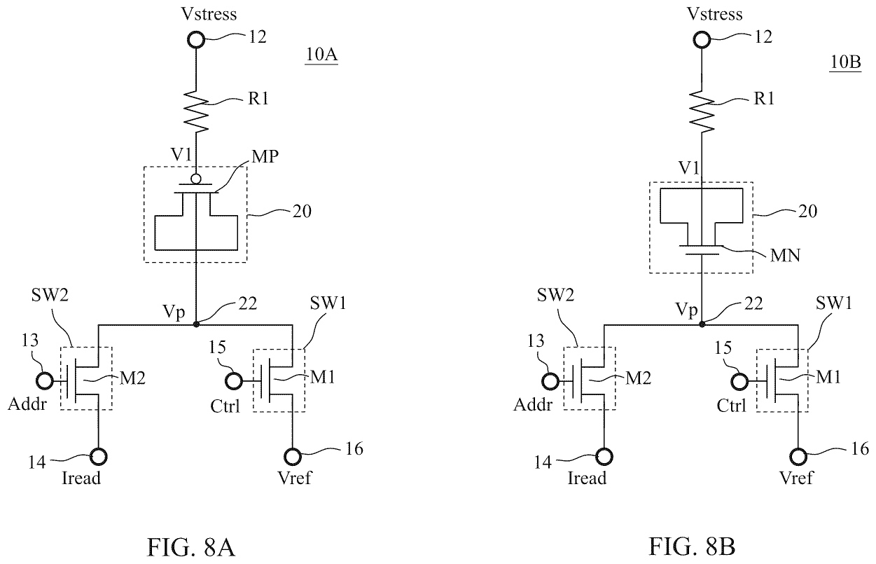

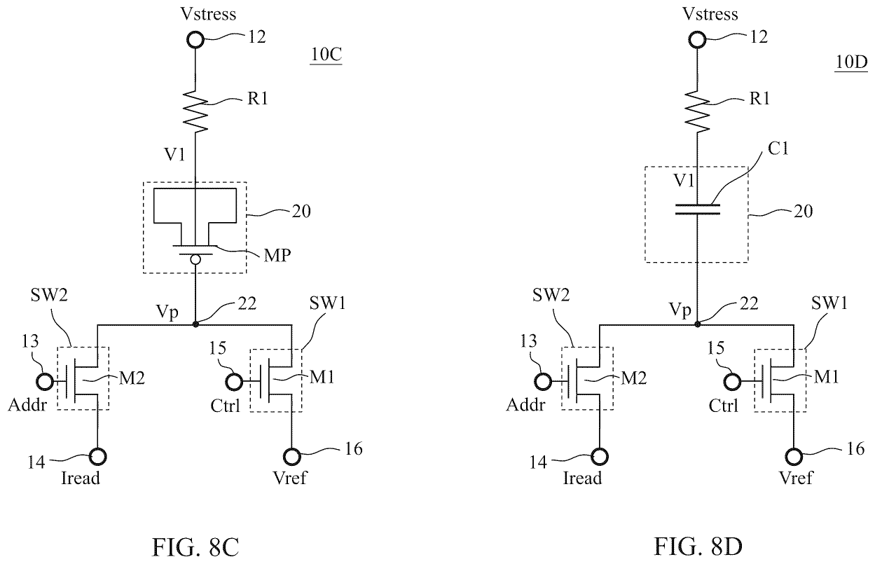

FIGS. 8A through 8D are circuit diagrams of various test unit circuits, in accordance with some embodiments of the disclosure. In FIGS. 8A through 8D, the resistor R1 is connected between the DUT 20 and the input terminal 12. In the example embodiments of FIGS. 8A through 8D, the switches SW1 and SW2 are formed by the N-type transistors M1 and M2. In some embodiments, the switches SW1 and SW2 are formed by the P-type transistors or other type of switching devices.

In FIG. 8A, a test unit circuit 10A is shown. The test unit circuit 10A of FIG. 8A is similar to the test unit circuit 10 of FIG. 2, and the difference is that the DUT 20 of FIG. 8A is a P-type transistor MP. The gate of the P-type transistor MP is connected to the resistor R1, and the bulk of the P-type transistor MP is connected to the intermediate node 22. Furthermore, the source and drain of the P-type transistor MP are connected to each other. The voltage V1 represents a gate voltage of the P-type transistor MP, and a voltage Vp represents the voltage at the intermediate node 22 (i.e., a bulk voltage of the P-type transistor MP).

In FIG. 8B, a test unit circuit 10B is shown. The test unit circuit 10B is similar to the test unit circuit 10 of FIG. 2, and the difference is that in the gate of the N-type transistor MN is connected to the intermediate node 22 and the bulk of the N-type transistor MN is connected to the resistor R1 in the test unit circuit 10B of FIG. 8B. The voltage V1 represents a bulk voltage of the N-type transistor MN, and a voltage Vp represents the voltage at the intermediate node 22 (i.e., a gate voltage of the N-type transistor MN).

In FIG. 8C, a test unit circuit 10C is shown, similar to the test unit circuit 10B of FIG. 8B, and differing therefrom in the DUT 20 of FIG. 8C being a P-type transistor MP. The gate of the P-type transistor MP is connected to the intermediate node 22, and the bulk of the P-type transistor MP is connected to the resistor R1. The voltage V1 represents a bulk voltage of the P-type transistor MP, and a voltage Vp represents the voltage at the intermediate node 22 (i.e., a gate voltage of the P-type transistor MP).

In FIG. 8D, a test unit circuit 10D is shown, similar to the test unit circuit 10 of FIG. 2, and differing therefrom in the DUT 20 of FIG. 8D being a capacitor C1. A first electrode of the capacitor C1 is connected to the resistor R1 and a second electrode of the capacitor C1 is connected to the intermediate node 22. The voltage V1 represents a voltage at the first electrode of the capacitor C1, and a voltage Vp represents a voltage at the second electrode of the capacitor C1. In some embodiments, the DUT 20 is a structure formed by two adjacent metal or conductive features for testing or evaluating dielectric breakdown between the two adjacent metal or conductive features.

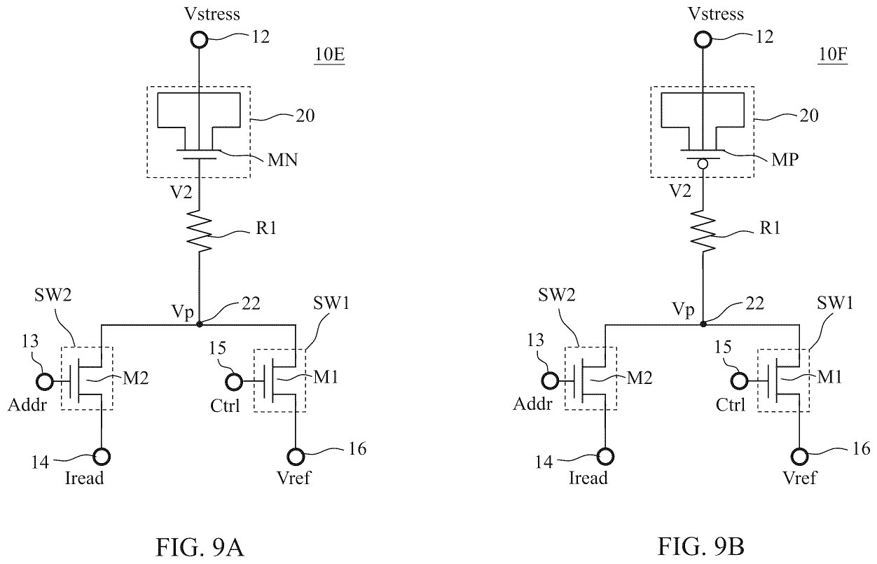

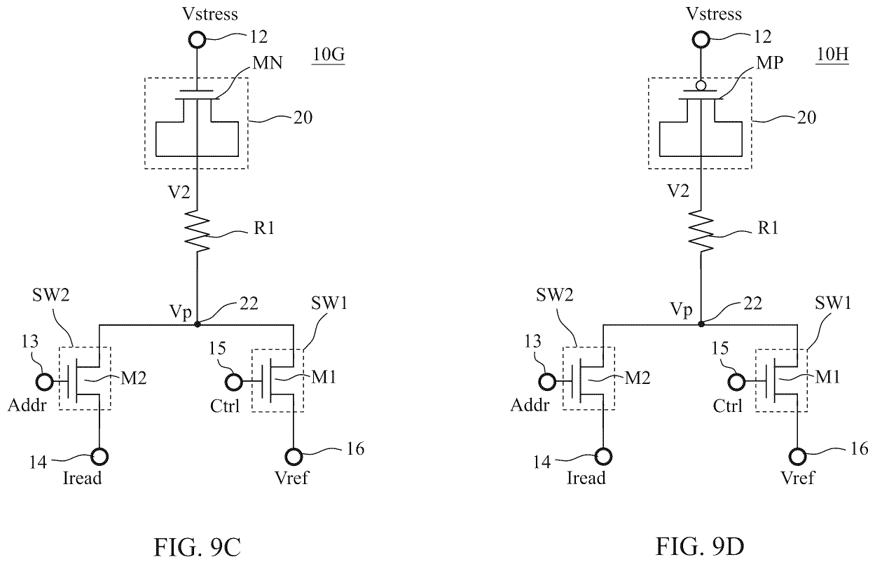

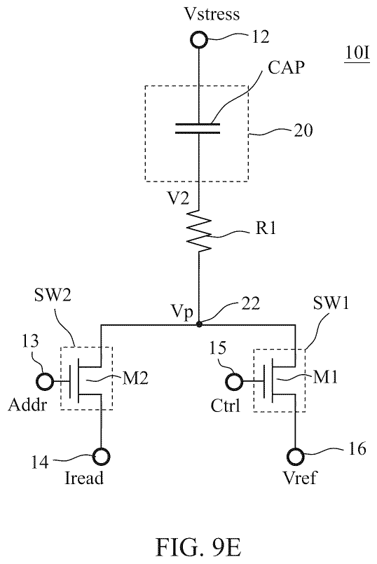

FIGS. 9A through 9E are circuit diagrams of various test unit circuits, in accordance with some embodiments of the disclosure. In FIGS. 9A through 9E, the DUT 20 is connected between the resistor R1 and the input terminal 12. In the example embodiments of FIGS. 9A through 9E, the switches SW1 and SW2 are formed by the N-type transistors M1 and M2. In some embodiments, the switches SW1 and SW2 are formed by the P-type transistors or other type of switching devices.

In FIG. 9A, a test unit circuit 10E is shown. The DUT 20 is an N-type transistor MN. Bulk and gate of the N-type transistor MN are connected to the input terminal 12 and the resistor R1, respectively, and the source and drain of the N-type transistor MN are connected. The resistor R1 is connected between the DUT 20 and the intermediate node 22. The stress voltage Vstress is applied to the bulk of the N-type transistor MN, and a voltage V2 at a node between the DUT 20 and the resistor R1 represents a gate voltage of the N-type transistor MN. Furthermore, the voltages V2 and Vp represent the voltages at two ends of the resistor R1. When the DUT 20 is normal, the voltage V2 substantially equals 0 during a global stress operation and a read operation. As described, the resistor R1 is configured as a current limiting resistor (e.g., with a high resistance of, for example, 1 KΩ to 10 MΩ), for limiting the leakage current of the DUT 20 when the DUT 20 is broken down. Therefore, during the global stress operation, when the DUT 20 is broken down, the voltage V2 substantially equals

$$V L 1 \times \frac{R 1 + R 3}{R 1 + R 2 + R 3} ,$$

and the voltage Vp substantially equals

$$V L 1 \times \frac{R 3}{R 1 + R 2 + R 3} .$$

During the read operation, when the DUT 20 is broken down, the voltage V2 substantially equals

$$V L 2 \times \frac{R 1 + R 3}{R 1 + R 2 + R 3} ,$$

and the voltage Vp substantially equals substantially equals

$$V L 2 \times \frac{R 3}{R 1 + R 2 + R 3} .$$

In FIG. 9B, a test unit circuit 10F is shown, similar to the test unit circuit 10E of FIG. 9A, and differing therefrom in the DUT 20 of the test unit circuit 10F being a P-type transistor MP. The stress voltage Vstress is applied to the bulk of the P-type transistor MP, and the voltage V2 represents a gate voltage of the P-type transistor MP.

In FIG. 9C, a test unit circuit 10G is shown, similar to the test unit circuit 10E of FIG. 9A, and differing therefrom in the gate of the N-type transistor MN being connected to the input terminal 12 and the bulk of the N-type transistor MN being connected to the resistor R1 in the test unit circuit 10G of FIG. 9C. The stress voltage Vstress is applied to the gate of the N-type transistor MN, and the voltage V2 represents the bulk voltage of the N-type transistor MN.

In FIG. 9D, a test unit circuit 10H is shown, similar to the test unit circuit 10G of FIG. 9C, and differing therefrom in the DUT 20 of the test unit circuit 10H being a P-type transistor MP. The stress voltage Vstress is applied to the gate of the P-type transistor MP, and the voltage V2 represents a bulk voltage of the P-type transistor MP.

In FIG. 9E, a test unit circuit 10I is shown, similar to the test unit circuit 10E of FIG. 9A, and differing therefrom in the DUT 20 of FIG. 9E being a capacitor C1. A first electrode of the capacitor C1 is connected to the input terminal 12 and a second electrode of the capacitor C1 is connected to the resistor R1. The stress voltage Vstress is applied to the first electrode of the capacitor C1, and the voltage V2 represents a voltage of the second electrode of the capacitor C1. In some embodiments, the DUT 20 is a structure formed by two adjacent metal or conductive features for testing or evaluating dielectric breakdown between the two adjacent metal or conductive features.

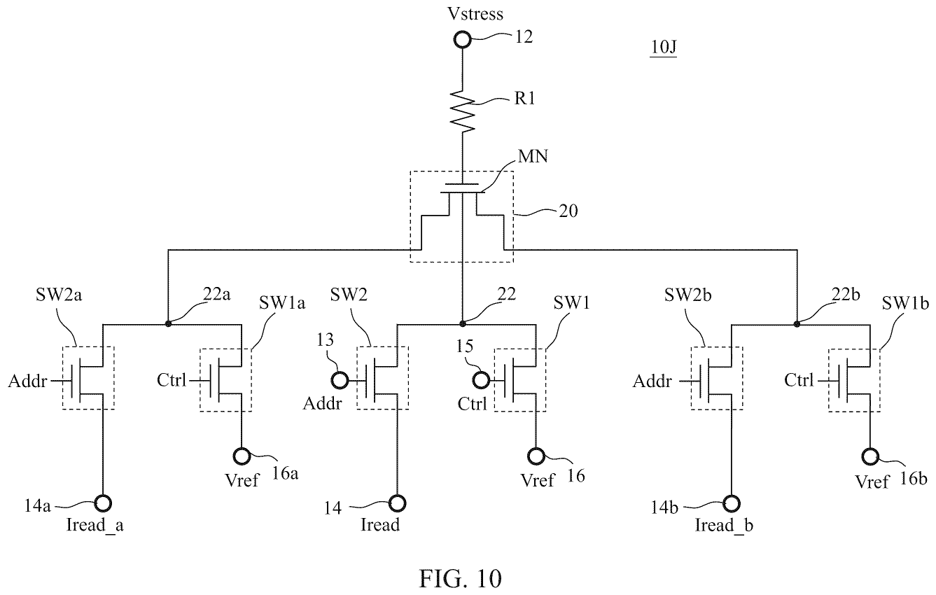

FIG. 10 is a circuit diagram of a test unit circuit 10J, in accordance with some embodiments of the disclosure. In the test unit circuit 10J, the resistor R1 is connected between the DUT 20 and the input terminal 12. The test unit circuit 10J of FIG. 10 is similar to the test unit circuit 10 of FIG. 2, differing therefrom in the DUT 20 of FIG. 10 being connectable to multiple stress paths during one or more global stress operations and connectable to multiple read paths during one or more read operations. In some embodiments, the DUT 20 is the P-type transistor MP.

In FIG. 10, the source of the N-type transistor MN is connected to the intermediate node 22a, and the drain of the N-type transistor MN is connected to the intermediate node 22b. Moreover, the test unit circuit 10J further includes the switches SW1a, SW1b, SW2a, and SW2b. The switches SW1a, SW1b, SW2a, and SW2b have equivalent resistance R3. In the example embodiment of FIG. 10, all switches are formed by the N-type transistors. In some embodiments, all switches are formed by the P-type transistors or other type of switching devices, or at least one of the switches is an N-type transistor and at least another one of the switches is a P-type transistor.

The switch SW1a is connected between the intermediate node 22a and the reference terminal 16a and controlled by the control signal Ctrl, and the reference terminal 16a is configured to receive the reference voltage Vref from the test machine through an additional test line. In some embodiments, the switch SW1a is connected between the intermediate node 22a and the reference terminal 16 so as to receive the reference voltage Vref through the corresponding test line 113 of FIG. 1. When the switch SW1a is turned on by the control signal Ctrl, the turned-on switch SW1a is configured to provide an additional stress path for the DUT 20. The switch SW2a is connected between the intermediate node 22a and the output terminal 14a, and is controlled by the address signal Addr. When the switch SW2a is turned on by the address signal Addr, the turned-on switch SW2a is configured to provide an additional read path for the DUT 20.

The switch SW1b is connected between the intermediate node 22b and the reference terminal 16b, and controlled by the control signal Ctrl, and the reference terminal 16b is configured to receive the reference voltage Vref from the test machine through an additional test line. In some embodiments, the switch SW1b is connected between the intermediate node 22b and the reference terminal 16 so as to receive the reference voltage Vref through the corresponding test line 113 of FIG. 1. When the switch SW1b is turned on by the control signal Ctrl, the turned-on switch SW1b is configured to provide an additional stress path for the DUT 20. The switch SW2b is connected between the intermediate node 22b and the output terminal 14b, and is controlled by the address signal Addr. When the switch SW2b is turned on by the address signal Addr, the turned-on switch SW2b is configured to provide an additional read path for the DUT 20.

In some embodiments, the output terminals 14, 14a and 14b are connected to corresponding individual test lines (e.g., 112 of FIG. 1) for respectively providing the currents Iread, Iread_a and Iread_b to the test machine. The current Iread is a leakage current from the gate to bulk of the N-type transistor MN, the current Iread_a is a leakage current from the gate to source of the N-type transistor MN, and the current Iread_b is a leakage current from the gate to drain of the N-type transistor MN. Through the read paths provided by the switches SW2a and SW2b, the TDDB test is performed on the spacers of the N-type transistor MN.

In the example embodiment of FIG. 10, the switches SW1, SW1a, and SW1b are controlled by the same control signal Ctrl, and the switches SW2, SW2a and SW2b are controlled by the same address signal Addr. In some embodiments, the switches SW1, SW1a, and SW1b are controlled by different control signals, and only one thereof is turned on at a time. In some embodiments, the switches SW2, SW2a and SW2b are controlled by different control signals, and only one thereof is turned on at a time.

According to some embodiments, a measurement circuit is provided. The measurement circuit includes an array including a plurality of test unit circuits arranged in rows and columns, a plurality of first test lines, a plurality of address lines, and a control circuit connected to the plurality of address lines. Each of the plurality of test unit circuits includes a device under test, a resistor coupled in series with the device under test between an input terminal and an intermediate node, a first switch coupled between the intermediate node and a node of a reference voltage, and a second switch coupled between the intermediate node and an output terminal. Each of the plurality of first test lines is connected to the first switches of the test unit circuits in a corresponding column among the columns of the array. Each of the plurality of address lines is connected to the second switches of the test unit circuits in a corresponding row among the rows of the array.

According to some embodiments, a test unit circuit is provided. The test unit circuit includes a device under test, a resistor coupled in series with the device under test between an input terminal and an intermediate node, a first switch coupled between the intermediate node and a node of a reference voltage, and a second switch coupled between the intermediate node and an output terminal. During a stress operation, the first switch is configured to be turned on, the second switch is configured to be turned off, and the input terminal is configured to receive a stress voltage with a first voltage level. During a read operation, the first switch is configured to be turned off, the second switch is configured to be turned on, and the input terminal is configured to receive the stress voltage with a second voltage level lower than the first voltage level.

According to some embodiments, a method is provided. The method includes performing a test cycle including: performing a global stress operation on an array formed by a plurality of test unit circuits arranged in a plurality of rows and a plurality of columns, to apply a stress voltage with a first voltage level to the plurality of test unit circuits and turn on a stress path in each of the plurality of test unit circuits, wherein each of the plurality of test unit circuits includes a device under test; sequentially performing a read operation on each row of the plurality of rows of the array after the global stress operation is performed, to apply the stress voltage with a second voltage level to the test unit circuits in said row and obtain a leakage current through a read path of each of the test unit circuits in said row; and flagging, among the plurality of test unit circuits, a test unit circuit having the leakage current that exceeds a threshold value as damaged. The second voltage level is lower than the first voltage level. The stress path is independent of the read path in each of the plurality of test unit circuits.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A measurement circuit, comprising:
an array comprising a plurality of test unit circuits arranged in rows and columns, wherein each of the plurality of test unit circuits comprises:
a device under test;
a resistor coupled in series with the device under test between an input terminal and an intermediate node;
a first switch coupled between the intermediate node and a node of a reference voltage; and
a second switch coupled between the intermediate node and an output terminal;
a plurality of first test lines each connected to the first switches of the test unit circuits in a corresponding column among the columns of the array;
a plurality of address lines each connected to the second switches of the test unit circuits in a corresponding row among the rows of the array; and
a control circuit connected to the plurality of address lines.

2. The measurement circuit of claim 1, wherein
during a stress operation, the first switch is configured to be turned on and the control circuit is configured to turn off the second switch in each of the plurality of test unit circuits of the array, and
during a read operation,
the first switch is configured to be turned off in each of the plurality of test unit circuits of the array, and
the control circuit is configured to turn on the second switch in each of the test unit circuits in a row among the rows of the array.

3. The measurement circuit of claim 2, wherein
during the stress operation, the input terminal of each of the plurality of test unit circuits is configured to receive a stress voltage with a first voltage level, and
during the read operation, the input terminal of each of the plurality of test unit circuits is configured to receive the stress voltage with a second voltage level lower than the first voltage level.

4. The measurement circuit of claim 1, further comprising:
a plurality of second test lines each connected to the output terminals of the test unit circuits in a corresponding column among the columns of the array.

5. The measurement circuit of claim 1, wherein in each of the plurality of test unit circuits,
the resistor is coupled between the input terminal and the device under test, and
the device under test is coupled between the resistor and the intermediate node.

6. The measurement circuit of claim 1, wherein in each of the plurality of test unit circuits,
the device under test is coupled between the input terminal and the resistor, and
the resistor is coupled between the device under test and the intermediate node.

7. The measurement circuit of claim 1, wherein in each of the plurality of test unit circuits,
the device under test is a transistor,
one of a gate and a bulk of the transistor is connected to the resistor, and
the other of the gate and the bulk of the transistor is connected to the intermediate node or the input terminal.

8. The measurement circuit of claim 1, wherein in each of the plurality of test unit circuits,
the device under test is a capacitor,
a first electrode of the capacitor is connected to the resistor, and
a second electrode of the capacitor is connected to the intermediate node or the input terminal.

9. The measurement circuit of claim 1, wherein in each of the plurality of test unit circuits,
the device under test is a transistor,
wherein a gate of the transistor is coupled to the resistor, and
a source or a drain of the transistor is connected to the intermediate node.

10. The measurement circuit of claim 1, wherein a resistance of the resistor exceeds an equivalent resistance of the device under test, and the equivalent resistance of the device under test exceeds an equivalent resistance of the first or second switch.

11. A test unit circuit, comprising:
a device under test;
a resistor coupled in series with the device under test between an input terminal and an intermediate node;
a first switch coupled between the intermediate node and a node of a reference voltage; and
a second switch coupled between the intermediate node and an output terminal,
wherein during a stress operation,
the first switch is configured to be turned on,
the second switch is configured to be turned off, and
the input terminal is configured to receive a stress voltage with a first voltage level, and
wherein during a read operation,
the first switch is configured to be turned off,
the second switch is configured to be turned on, and
the input terminal is configured to receive the stress voltage with a second voltage level lower than the first voltage level.

12. The test unit circuit of claim 11, wherein a resistance of the resistor exceeds an equivalent resistance of the device under test.

13. The test unit circuit of claim 12, wherein the equivalent resistance of the device under test exceeds an equivalent resistance of the first or second switch.

14. The test unit circuit of claim 11, wherein the device under test is a transistor, one of a gate and a bulk of the transistor is connected to the resistor, and the other of the gate and the bulk of the transistor is connected to the intermediate node or the input terminal.

15. The test unit circuit of claim 11, wherein the device under test is a capacitor, a first electrode of the capacitor is connected to the resistor, and a second electrode of the capacitor is connected to the intermediate node or the input terminal.

16. The test unit circuit of claim 11, wherein the device under test is a transistor, a gate of the transistor is coupled to the resistor, and a source or a drain of the transistor is coupled to the intermediate node.

17. A method, comprising:
performing a test cycle comprising:
performing a global stress operation on an array formed by a plurality of test unit circuits arranged in a plurality of rows and a plurality of columns, to apply a stress voltage with a first voltage level to the plurality of test unit circuits and turn on a stress path in each of the plurality of test unit circuits, wherein each of the plurality of test unit circuits comprises a device under test;
sequentially performing a read operation on each row of the plurality of rows of the array after the global stress operation is performed, to apply the stress voltage with a second voltage level to the test unit circuits in said row and obtain a leakage current through a read path of each of the test unit circuits in said row; and
flagging, among the plurality of test unit circuits, a test unit circuit having the leakage current that exceeds a threshold value as damaged,
wherein the second voltage level is lower than the first voltage level, and
wherein the stress path is independent of the read path in each of the plurality of test unit circuits.

18. The method of claim 17, further comprising:
storing and updating a map of one or more test unit circuits, among the plurality of test unit circuits, that have been flagged as damaged.

19. The method of claim 18, further comprising:
repeating the test cycle one or more times,
wherein, while sequentially performing the read operation when the test cycle is repeated, the leakage currents of the one or more test unit circuits that have been flagged in the map, are not measured or are ignored.

20. The method of claim 17, wherein
the test cycle comprises performing the global stress operation more than one time before sequentially performing the read operation on each row of the plurality of rows.
